(19) United States
(12) Patent Application Publication
(10) Pub. No.: US 2026/0068759 A1
(43) Pub. Date: Mar. 5, 2026

(54) SEMICONDUCTOR PACKAGE AND METHOD OF FABRICATING THE SAME

(71) Applicant: Samsung Electronics Co., Ltd., Suwon-si (KR)

(72) Inventors: Eunkyung BAEK, Suwon-si (KR); Youngjun PARK, Suwon-si (KR); YOONHA JUNG, Suwon-si (KR); SUNGHAWN BAE, Suwon-si (KR)

(21) Appl. No.: 19/095,290

(22) Filed: Mar. 31, 2025

(30) Foreign Application Priority Data
Sep. 5, 2024 (KR) 10-2024-0120827

(51) Int. Cl. H01L 25/11; H01L 23/00; H01L 23/31; H01L 23/36; H01L 23/538; H01L 25/00

(52) U.S. Cl. CPC H01L 25/117

(57) ABSTRACT

A semiconductor package includes a first sub-package, a second sub-package on the first sub-package, and a first inner connection terminal between the first and second sub-packages to electrically connect them to each other. The first sub-package includes a package substrate, a first chip on the package substrate, a first mold layer covering the package substrate and the first chip, and a first mold via provided next to the first chip to penetrate the first mold layer. The second sub-package includes second chips sequentially stacked to be offset from each other, the second chips including chip pads exposed through bottom surfaces thereof, a second mold layer covering the second chips, and a second mold via penetrating a portion of the second mold layer and contacting a chip pad of the uppermost one of the second chips. The first inner connection terminal contacts the first and second mold vias.

### CROSS-REFERENCE TO RELATED APPLICATIONS

This U.S. non-provisional patent application claims priority under 35 U.S.C. § 119 to Korean Patent Application No. 10-2024-0120827, filed on Sep. 5, 2024, in the Korean Intellectual Property Office, the entire contents of which are hereby incorporated by reference.

### BACKGROUND OF THE INVENTION

The present disclosure relates to a semiconductor package and a method of fabricating the same.

A semiconductor package is configured to facilitate the use of an integrated circuit chip as a component in an electronic product. In general, the semiconductor package includes a printed circuit board (PCB) and a semiconductor chip die, which is mounted on the PCB and is electrically connected to the PCB using bonding wires or bumps. With development of the electronics industry, many studies are being conducted to enhance reliability and durability of the semiconductor package.

### SUMMARY

An embodiment of the inventive concept provides a semiconductor package with high performance, high capacity, and high integration density.

An embodiment of the inventive concept provides a method of increasing a yield in a process of fabricating a semiconductor package.

The object of the present inventive concepts is not limited to the benefits mentioned above, and other objects which have not been mentioned above will be clearly understood to those skilled in the art from the following description.

According to an embodiment of the inventive concept, a semiconductor package may include a first sub-package, a second sub-package stacked on the first sub-package, and a first inner connection terminal interposed between the first and second sub-packages to electrically connect them to each other. The first sub-package may include a package substrate, a first chip mounted on the package substrate, a first mold layer covering the package substrate and the first chip, and a first mold via provided next to the first chip to penetrate the first mold layer. The second sub-package may include second chips, which are sequentially stacked to be offset from each other, the second chips including chip pads exposed through bottom surfaces thereof, a second mold layer covering the second chips, and a second mold via penetrating a portion of the second mold layer and to be in contact with a chip pad of the uppermost one of the second chips. The first inner connection terminal may be in contact with the first and second mold vias.

According to an embodiment of the inventive concept, a semiconductor package may include a first sub-package, a second sub-package stacked on the first sub-package, and a first inner connection terminal and a second inner connection terminal interposed between the first sub-package and the second sub-package to electrically connect them to each other. The first sub-package may include a package substrate, a first chip mounted on the package substrate, a first mold layer covering the package substrate and the first chip, and a first mold via and a second mold via provided next to the first chip to penetrate the first mold layer. The second sub-package may include at least three second chips, which are sequentially stacked to be offset from each other, the second chips including chip pads exposed through bottom surfaces thereof, a second mold layer covering the second chips, a third mold via penetrating a portion of the second mold layer and contacting a chip pad of the uppermost one of the second chips, and a fourth mold via penetrating a portion of the second mold layer and electrically connected to a chip pad of an intermediate one of the second chips. The first inner connection terminal may vertically overlap the first and third mold vias, and the second inner connection terminal may vertically overlap the second and fourth mold vias. The third mold via may have a first height and a first width, and the fourth mold via may have a second height and a second width. The second height may be smaller than the first height, and the second width may be larger than the first width. An aspect ratio of each of the first and second mold vias may be in a range from 6 to 1000.

According to an embodiment of the inventive concept, a semiconductor package may include a first sub-package, a second sub-package stacked on the first sub-package, and a first inner connection terminal interposed between the first sub-package and the second sub-package to electrically connect them to each other. The first sub-package may include a package substrate, a first chip mounted on the package substrate, a first mold layer covering the package substrate and the first chip, and a first mold via provided next to the first chip to penetrate the first mold layer. The second sub-package may include second chips, which are sequentially stacked to be offset from each other, the second chips including chip pads exposed through bottom surfaces thereof, a second mold layer covering the second chips, and a second mold via penetrating a portion of the second mold layer and contacting a chip pad of the uppermost one of the second chips. The lowermost one of the second chips may further include at least one dummy pad, which is provided on a bottom surface thereof and is in contact with the first chip.

According to an embodiment of the inventive concept, a method of fabricating a semiconductor package may include fabricating a first sub-package, fabricating a second sub-package, and inverting the second sub-package to mount the second sub-package on the first sub-package. The fabricating of the first sub-package may include forming a first mold via on a package substrate, mounting a first chip on the package substrate, forming a first mold layer to cover the first chip and the first mold via, and performing a grinding process on the first mold layer to expose the first mold via. The fabricating of the second sub-package may include stacking second chips on a carrier substrate, the second chips including chip pads provided on end portions thereof, the second chips being stacked in such a way that the chip pads are offset from each other, forming a second mold via to contact a chip pad of the lowermost one of the second chips, forming a second mold layer to cover the second mold via and the second chips, forming an inner connection terminal on the second mold via, and removing the carrier substrate. The mounting of the second sub-package on the first sub-package may be performed to electrically connect the first mold via to the second mold via through the inner connection terminal.

### BRIEF DESCRIPTION OF THE DRAWINGS

FIG. 1 is a sectional view illustrating a semiconductor package according to an embodiment of the inventive concept.

FIGS. 2A to 2C are enlarged sectional views illustrating a portion ‘P1’ of FIG. 1.

FIGS. 3A to 3E are sectional views illustrating a process of fabricating a first sub-package of FIG. 1.

FIGS. 4A to 4D are sectional views illustrating a process of fabricating a second sub-package of FIG. 1.

FIG. 5 is a sectional view illustrating a process of fabricating the semiconductor package of FIG. 1.

FIG. 6 is a sectional view illustrating a semiconductor package according to an embodiment of the inventive concept.

FIG. 7 is a sectional view illustrating a semiconductor package according to an embodiment of the inventive concept.

FIG. 8 is a sectional view illustrating a semiconductor package according to an embodiment of the inventive concept.

FIG. 9 is a sectional view illustrating a semiconductor package according to an embodiment of the inventive concept.

FIG. 10 is a sectional view illustrating a semiconductor package according to an embodiment of the inventive concept.

FIG. 11 is a sectional view illustrating a semiconductor package according to an embodiment of the inventive concept.

### DETAILED DESCRIPTION

Example embodiments of the inventive concepts will now be described more fully with reference to the accompanying drawings, in which example embodiments are shown. In this description, such terms as “first” and “second” may be used to simply distinguish identical or similar components from each other, and the sequence of such terms may be changed in accordance with the order of mention.

As used herein, components described as being “electrically connected” are configured such that an electrical signal can be transferred from one component to the other (although such electrical signal may be attenuated in strength as it is transferred and may be selectively transferred).

Spatially relative terms, such as “vertical,” “horizontal,” “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

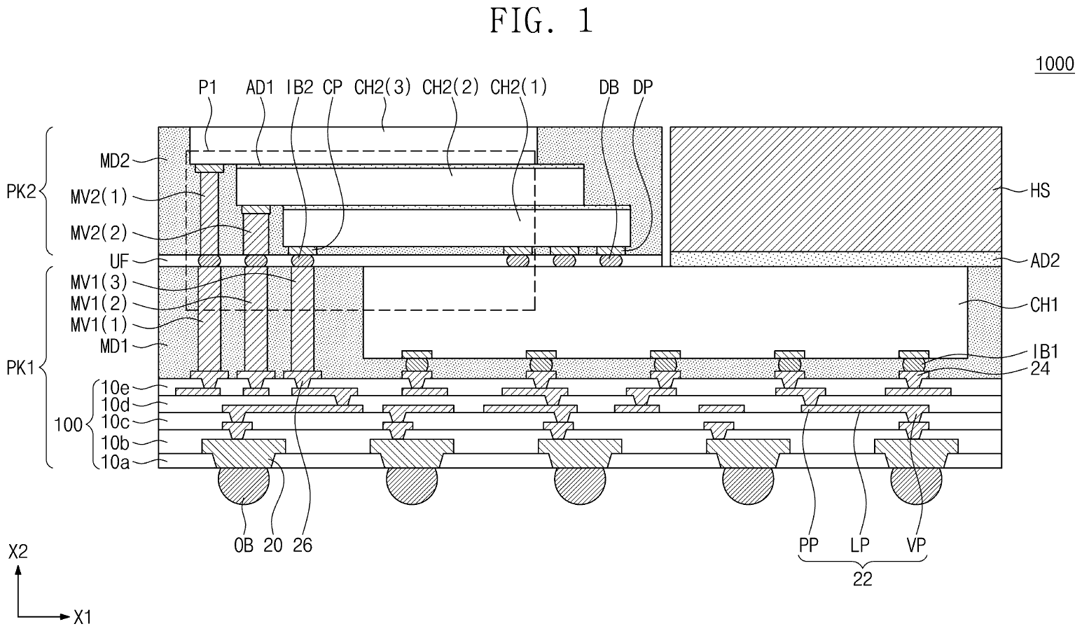

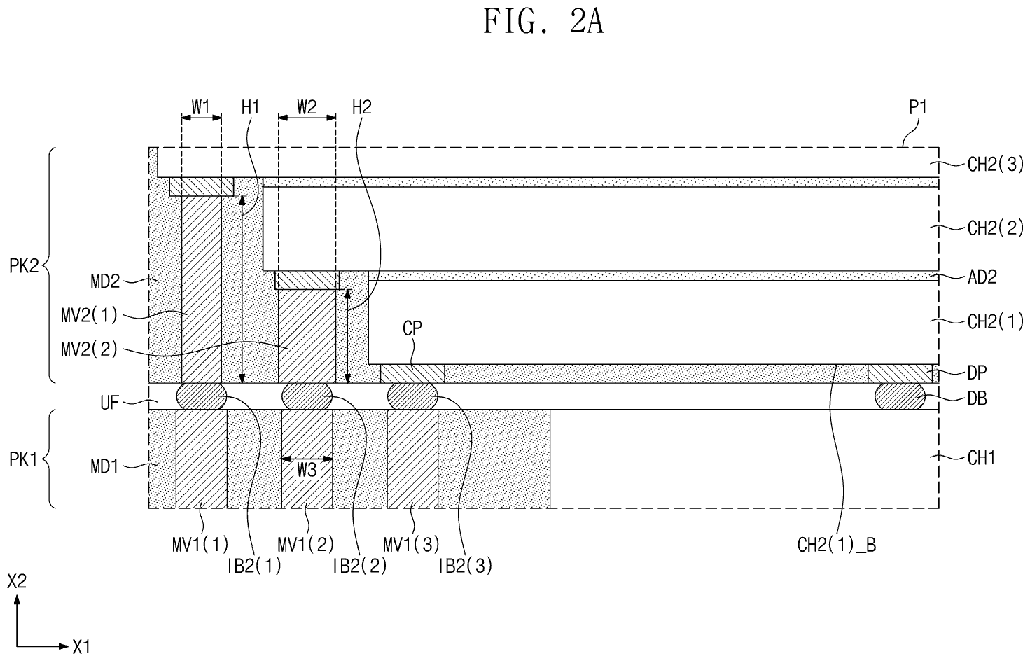

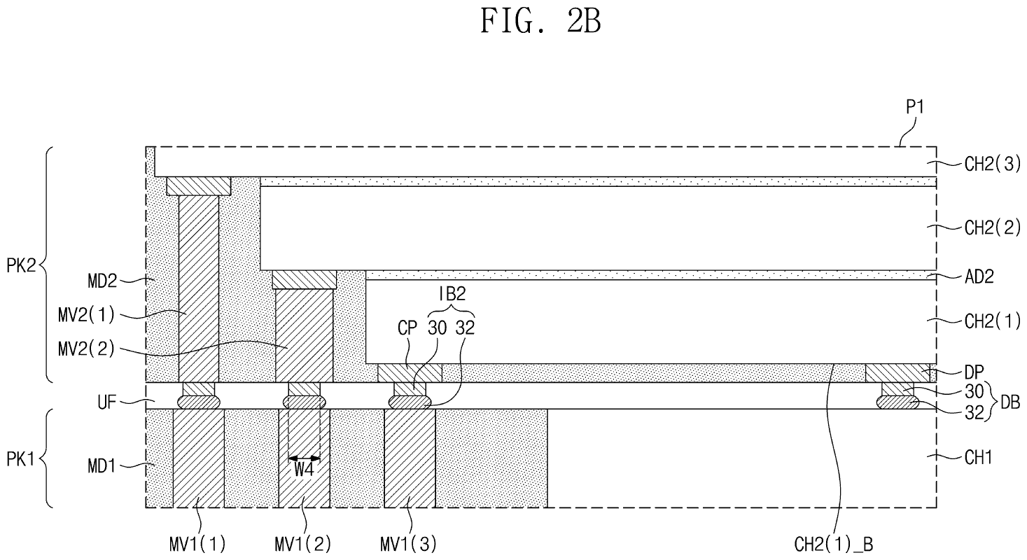

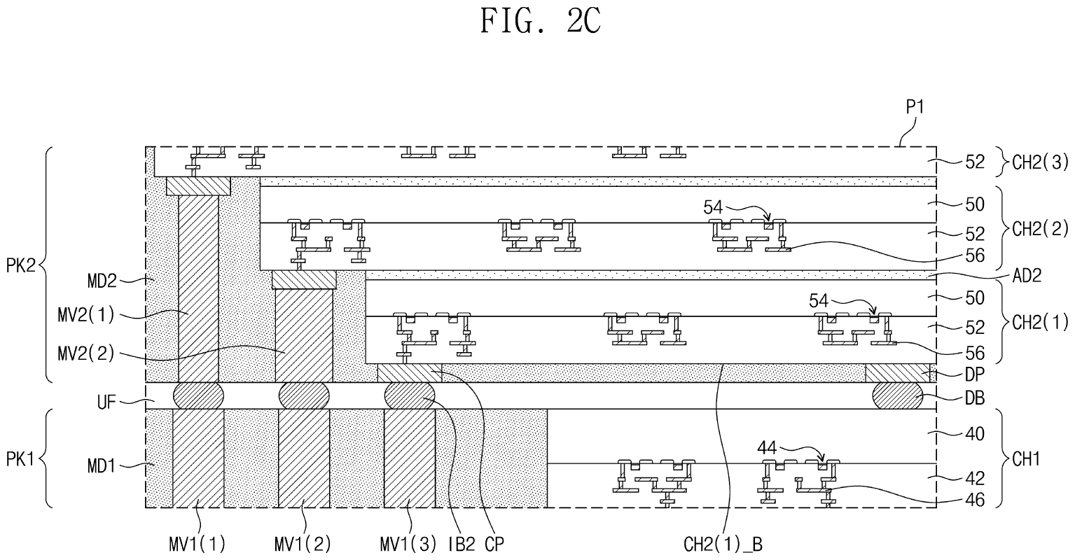

FIG. 1 is a sectional view illustrating a semiconductor package according to an embodiment of the inventive concept. FIGS. 2A to 2C are enlarged sectional views illustrating a portion ‘P1’ of FIG. 1.

Referring to FIG. 1, a semiconductor package 1000 in the present embodiment may include a first sub-package PK1, a second sub-package PK2, and a heat-dissipation member HS. The semiconductor package 1000 may have a package-on-package structure. The second sub-package PK2 may be mounted on the first sub-package PK1. The heat-dissipation member HS may be placed on the first sub-package PK1 and next to the second sub-package PK2.

The first sub-package PK1 may include a package substrate 100, a first chip structure CH1, a first mold layer MD1, and first mold vias MV1. The package substrate 100 may be a redistribution substrate. The package substrate 100 may include substrate insulating layers 10a to 10e, substrate lower pads 20, substrate inner interconnection lines 22, and substrate upper pads 24 and 26 sequentially stacked. In the present embodiment, each of the substrate insulating layers 10a to 10e may be a photoimageable dielectric (PID) layer. The substrate lower pads 20, the substrate inner interconnection lines 22, and the substrate upper pads 24 and 26 may be formed of or include a conductive material (e.g., copper). Although not shown, bottom and side surfaces of the substrate lower pads 20, the substrate inner interconnection lines 22, and the substrate upper pads 24 and 26 may be covered with a diffusion barrier layer. The diffusion barrier layer may be formed of or include at least one of materials (e.g., Ti, TiN, Ta, and TaN). Each of the substrate inner interconnection lines 22 may include a via portion (e.g., a via) VP, a line portion (e.g., a conductive line) LP, and a pad portion (e.g., a pad) PP. In the present embodiment, the via portion VP may be placed below the line portion LP to penetrate one of the substrate insulating layers 10a to 10e. The via portion VP, the line portion LP, and the pad portion PP may be provided to form a single object. For example, the via portion VP, the line portion LP, and the pad portion PP may be integrally formed.

Each of the substrate lower and upper pads 20, 24, and 26 may have a ‘T’-shaped section. Outer connection terminals OB may be bonded to the substrate lower pads 20, respectively. Each of the outer connection terminals OB may include at least one of conductive bumps, conductive pillars, and solder balls. For example, the outer connection terminals OB may be bumps, conductive pillars or solder balls. Each of the outer connection terminals OB may be formed of or include at least one of copper, nickel, gold, aluminum, tin, and silver.

The substrate upper pads 24 and 26 may include first substrate upper pads 24 and second substrate upper pads 26. A width of each of the first substrate upper pads 24 may be different from a width of each of the second substrate upper pads 26. For example, the width of each of the second substrate upper pads 26 may be larger than the width of each of the first substrate upper pads 24. For example, the widths of the substrate upper pads 24 and 26 may be measured in a horizontal direction, e.g., parallel with a side of the package substrate 100.

The first chip structure CH1 may be electrically connected to the first substrate upper pads 24 using first inner connection members IB1. In the present specification, the term ‘chip structure’ may indicate a semiconductor chip or semiconductor die. For example, the first chip structure CH1 may be a chip (e.g., a semiconductor chip or a semiconductor die). The first chip structure CH1 may be one selected from a logic circuit chip, a microelectromechanical system (MEMS) chip, an application-specific integrated circuit (ASIC) chip, a general-purpose computing on graphics processing units (GPGPU) chip, or a graphics double data rate (GDDR) chip. Each of the first inner connection members IB1 may be an inner connection terminal including at least one of conductive bumps, conductive pillars, or solder layers. For example, the first inner connection members IB1 may be bumps, conductive pillars, solder balls, or solder layers. Each of the first inner connection members IB1 may be formed of or include at least one of copper, nickel, gold, aluminum, tin, or silver.

The first mold layer MD1 may cover the first chip structure CH1 and the package substrate 100. For example, the first mold layer MD1 may contact side surfaces and a bottom surface of the first chip structure CH1 and an upper surface of the package substrate 100. The first mold layer MD1 may fill a space between the first chip structure CH1 and the package substrate 100. The first mold layer MD1 may include an insulating resin (e.g., an epoxy-based molding compound (EMC)). The first mold layer MD1 may further include fillers, which are dispersed in the insulating resin. For example, the fillers may be particles formed of silica, alumina, zinc oxide, or boron nitride. A top surface of the first mold layer MD1 may be coplanar with a top surface of the first chip structure CH1.

The first mold vias MV1 may be provided to penetrate the first mold layer MD1. The first mold vias MV1 may be bonded to the second substrate upper pads 26, respectively. The first mold vias MV1 may be placed next to the first chip structure CH1. The first mold vias MV1 may include the first of the first mold vias MV1(1), the second of the first mold vias MV1(2), and the third of the first mold vias MV1(3), which are arranged side-by-side in a first direction X1. Although the present embodiment illustrates an example, in which three first mold vias MV1 are provided, the number of the first mold vias MV1 is not limited to this example and may be one or more. Each of the first mold vias MV1 may have an aspect ratio of 6 to 1000. Top surfaces of the first mold vias MV1 may be coplanar with the top surface of the first mold layer MD1.

The second sub-package PK2 may include second chip structures CH2, a second mold layer MD2, and second mold vias MV2. Each of the second chip structures CH2 may be a FLASH memory chip (e.g., VNAND or NAND type), a DRAM chip, an SRAM chip, an EEPROM chip, a PRAM chip, an MRAM chip, or an ReRAM chip. For example, each of the second chip structures CH2 may be a chip (e.g., a semiconductor chip or a semiconductor die). The second chip structures CH2 may be stacked to be offset from each other. For example, the second chip structures CH2 may vertically overlap each other and side surfaces of the second chip structures CH2 are horizontally shifted from each other such that at least one side surface of each of the second chip structures CH2 does not vertically overlap the other side surfaces of the second chip structures CH2. Chip pads CP may be provided on bottom surfaces of the second chip structures CH2. The chip pads CP of the second chip structures CH2 may be offset from each other. For example, the chip pads CP of the second chip structures CH2 may not vertically overlap each other The chip pads CP may be formed of or include a conductive material (e.g., copper, nickel, and gold). The chip pads CP may be electrically connected to internal circuits in the second chip structures CH2, respectively. The second chip structures CH2 may include the first of the second chip structures CH2(1), the second of the second chip structures CH2(2), and the third of the second chip structures CH2(3), which are stacked in a second direction (e.g., a vertical direction) X2 perpendicular to a top surface of the package substrate 100. Although the present embodiment illustrates an example, in which three second chip structures CH2 are provided, the number of the second chip structures CH2 is not limited to this example and may be two or more.

A first adhesive layer AD1 may be interposed between the second chip structures CH2. The first adhesive layer AD1 may extend to form a top surface of at least one of the second chip structures CH2. The second mold layer MD2 may cover the second chip structures CH2. The second mold layer MD2 may include an insulating resin (e.g., an epoxy-based molding compound (EMC)). The second mold layer MD2 may further include fillers, which are dispersed in the insulating resin. For example, the fillers may be particles formed of silica, alumina, zinc oxide, or boron nitride. A top surface of the second mold layer MD2 may be coplanar with a top surface of the third of the second chip structures CH2(3), which is the uppermost one of the second chip structures CH2. For example, the top surface of the second mold layer MD2 may be coplanar with a top surface of the uppermost one of the second chip structures CH2.

The second mold layer MD2 may cover a bottom surface CH2(1)_B of the first of the second chip structures CH2(1), which is the lowermost one of the second chip structures CH2. For example, the second mold layer MD2 may cover and contact a bottom surface of the lowermost one of the second chip structures CH2. A bottom surface of a chip pad CP of the first of the second chip structures CH2(1) may not be covered with the second mold layer MD2 and may be exposed to the outside of the second mold layer MD2. The first of the second chip structure CH2(1) may further include dummy pads DP. The dummy pads DP may not be connected to, or may be electrically disconnected from, an internal circuit in the first of the second chip structures CH2(1). For example, the dummy pads DP may be electrically isolated such that no electrical signal is transferred to the dummy pads DP. Bottom surfaces of the dummy pads DP may not be covered with the second mold layer MD2 and may be exposed to the outside of the second mold layer MD2.

Referring to FIGS. 1 and 2A, the second mold vias MV2 may penetrate the second mold layer MD2 and may be in contact with some of the chip pads CP of the second chip structures CH2. The second mold vias MV2 may include the first of the second mold vias MV2(1) and the second of the second mold vias MV2(2), which are arranged side-by-side in the first direction (e.g., in a horizontal direction) X1. The first of the second mold vias MV2(1) may be in contact with a chip pad CP of the third of the second chip structure CH2(3), which is the uppermost one of the second chip structures CH2. The second of the second mold vias MV2(2) may be in contact with a chip pad CP of the second of the second chip structures CH2(2), which is an intermediate one of the second chip structures CH2.

Referring to FIG. 2A, the first of the second mold vias MV2(1) may have a first width W1 and a first height H1. The second of the second mold vias MV2(2) may have a second width W2 and a second height H2. The first width W1 may be equal to or different from the second width W2. For example, the first width W1 may be smaller than the second width W2. The first height H1 may be equal to or different from the second height H2. For example, the first height H1 may be larger than the second height H2.

The first mold vias MV1 may be provided to have the same size and the same shape. The first mold vias MV1 may be provided to have the same height. The first mold vias MV1 may have the same width (e.g., a third width W3). The third width W3 may be different from at least one of the first and second widths W1 and W2. For example, the widths W1, W3, and W3 of the mold vias may be measured in a horizontal direction (e.g., X1 direction).

Second inner connection members IB2 and dummy connection members DB may be interposed between the first and second sub-packages PK1 and PK2. The second inner connection members IB2 may electrically connect the first mold vias MV1 to the second mold vias MV2 and the chip pads CP and may be used as an electrical signal path. The second inner connection members IB2 may be connected to the first mold vias MV1 in a one-to-one correspondence. The second inner connection members IB2 may include the first of the second inner connection members IB2(1), the second of the second inner connection members IB2(2), and the third of the second inner connection members IB2(3), which are disposed/arranged in the first direction X1. Each of the second inner connection members IB2 may be an inner connection terminal including a conductive bump, a conductive pillar, a solder ball, and/or a solder layer.

The first of the second inner connection member IB2(1) may be interposed between the first of the first mold vias MV1(1) and the first of the second mold vias MV2(1) and may be in contact with them. The first of the second inner connection members IB2(1) may be vertically aligned to and/or vertically overlap the first of the first mold vias MV1(1) and the first of the second mold vias MV2(1). A side surface of the first of the first mold vias MV1(1) may not be aligned to a side surface of the first of the second mold vias MV2(1), e.g., in a vertical direction.

The second of the second inner connection member IB2(2) may be interposed between the second of the first mold vias MV1(2) and the second of the second mold vias MV2(2) and may be in contact with them. The second of the second inner connection member IB2(2) may be vertically aligned to and/or vertically overlap the second of the first mold vias MV1(2) and the second of the second mold vias MV2(2). A side surface of the second of the first mold vias MV1(2) may not be aligned to a side surface of the second of the second mold vias MV2(2), e.g., in a vertical direction.

The third of the second inner connection member IB2(3) may be interposed between the chip pad CP of the first of the second chip structures CH2(1) and the third of the first mold vias MV1(3) and may be in contact with them. The third of the second inner connection member IB2(3) may be vertically aligned with and/or may vertically overlap the chip pad CP of the first of the second chip structures CH2(1) and the third of the first mold vias MV1(3).

In the semiconductor package 1000 according to an embodiment of the inventive concept, an additional substrate (e.g., a printed circuit board, an interposer substrate, or a redistribution substrate) may not be interposed between the first and second sub-packages PK1 and PK2. Furthermore, the second sub-package PK2 may not include an additional substrate (e.g., a printed circuit board, an interposer substrate, or a redistribution substrate). The first mold vias MV1 may be directly connected to the second inner connection members IB2 and the second mold vias MV2 may be directly connected to the second inner connection members IB2. Thus, a signal connection distance between the second chip structures CH2 and the first chip structure CH1 may be shortened, and this may increase a signal transmission speed. In addition, a total vertical thickness of the semiconductor package 1000 may be reduced, and this may improve heat-dissipation efficiency. Since the second sub-package PK2 does not include a substrate, a horizontal length of the second sub-package PK2 may be reduced/minimized. Thus, a space for the heat-dissipation member HS may be provided on the first sub-package PK1. Due to the heat-dissipation member HS, the heat-dissipation performance of the semiconductor package 1000 may be further improved. Accordingly, malfunction issues may be reduced in the semiconductor package 1000 and reliability of the semiconductor package 1000 may be improved.

Referring to FIG. 2B, each of the second inner connection members IB2 may include a conductive bump 30 and a solder layer 32, which is placed below and bonded to the conductive bump 30. The conductive bump 30 may be formed of or include, for example, copper. The solder layer 32 may be formed of or include, for example, tin and silver. The conductive bump 30 may have a fourth width W4. The fourth width W4 may be different from at least one of the first to third widths W1 to W3 of FIG. 2A. The fourth width W4 may be smaller than the first to third widths W1 to W3. For example, the fourth width W4 may be measure in a horizontal direction (e.g., X1 direction). A pitch between the conductive bumps 30 may be in a range from about 0.1 μm to 50 μm. A distance between the conductive bumps 30 may be in a range from about 0.05 μm to 25 μm. In the case where the conductive bump 30 are used as a part of the second inner connection member IB2, it may be possible/helpful to further reduce the pitch between the conductive bumps 30.

The dummy connection members DB may not be applied with an electrical signal and may be used to prevent a distance between the first and second sub-packages PK1 and PK2 from being changed. For example, the dummy connection members DB may be helpful for maintaining uniform distance between the first and second sub-packages PK1 and PK2.

Referring to FIG. 2C, the first chip structure CH1 may include a first semiconductor substrate 40 and first transistors 44, a first interlayer insulating layer 42, and first interconnection lines 46, which are disposed on a bottom surface of the first semiconductor substrate 40. Each of the second chip structures CH2 may include a second semiconductor substrate 50 and second transistors 54, a second interlayer insulating layer 52, and second interconnection lines 56, which are disposed on a bottom surface of the second semiconductor substrate 50. The chip pads CP may be electrically connected to the second interconnection lines 56. The dummy connection members DB may not be electrically connected to the second interconnection lines 56. The dummy connection members DB may be in contact with the first semiconductor substrate 40.

An under-fill layer UF may be interposed between the first and second sub-packages PK1 and PK2. The under-fill layer UF may include a thermosetting resin layer or a photo-curable resin layer. The under-fill layer UF may further include organic fillers or inorganic fillers, which are dispersed in the resin layer. For example, the organic fillers or the inorganic fillers may be particles formed of silica, alumina, zinc oxide, or boron nitride.

The heat-dissipation member HS may be provided on the first sub-package PK1, and they may be bonded to each other by a second adhesive layer AD2 interposed therebetween. The heat-dissipation member HS may include at least one of metallic materials (e.g., copper, tungsten, titanium, and aluminum) or graphene, which have high thermal conductivity. A thickness of the second adhesive layer AD2 may be equal to or different from a thickness of the under-fill layer UF. The second adhesive layer AD2 may be a ‘thermal interface material (TIM) layer’. The second adhesive layer AD2 may include a thermosetting resin layer. The second adhesive layer AD2 may further include filler particles, which are dispersed in the thermosetting resin layer. The filler particles may include at least one of silica, alumina, zinc oxide, or boron nitride.

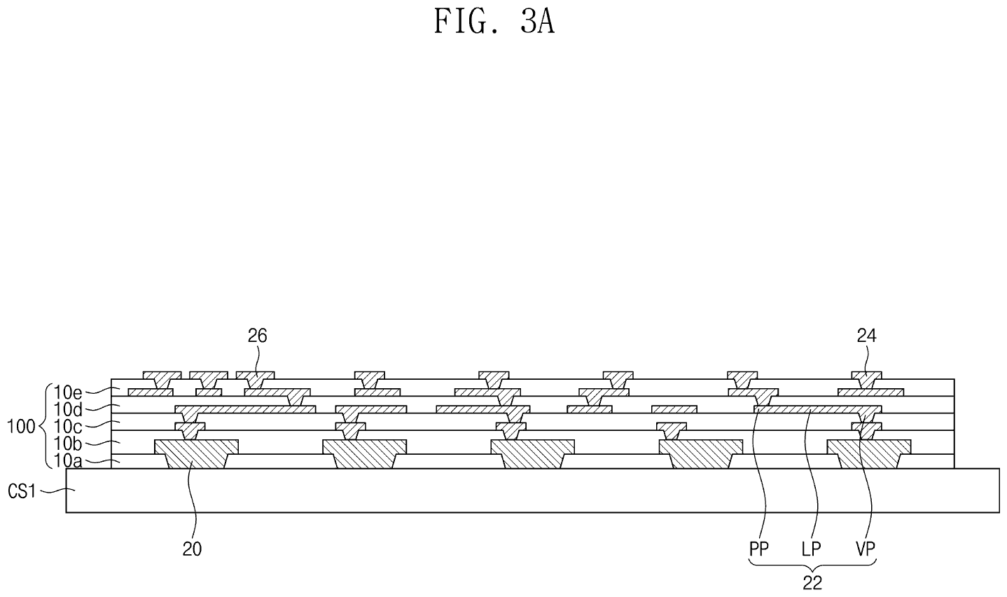

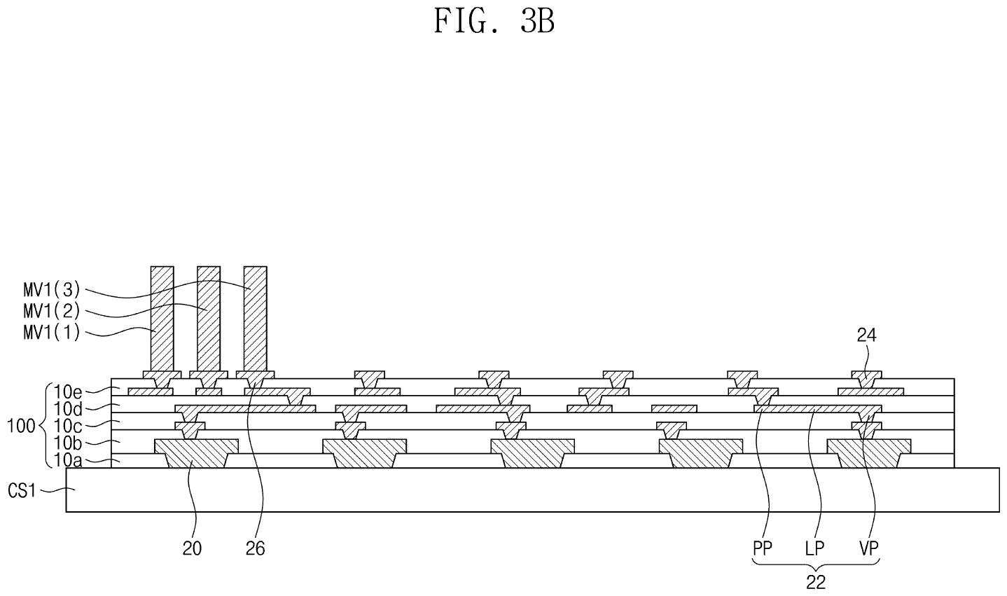

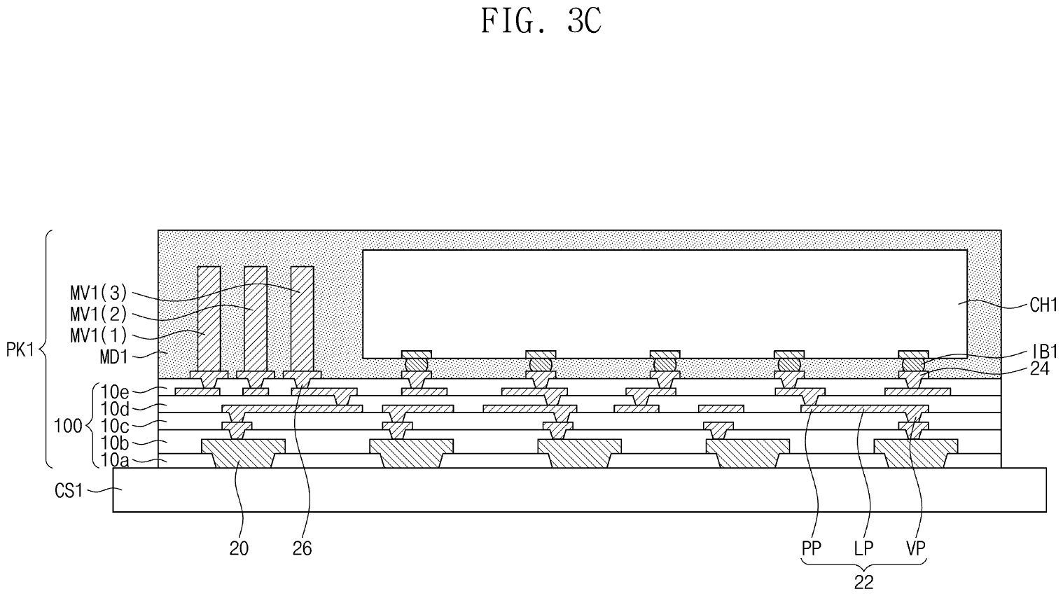

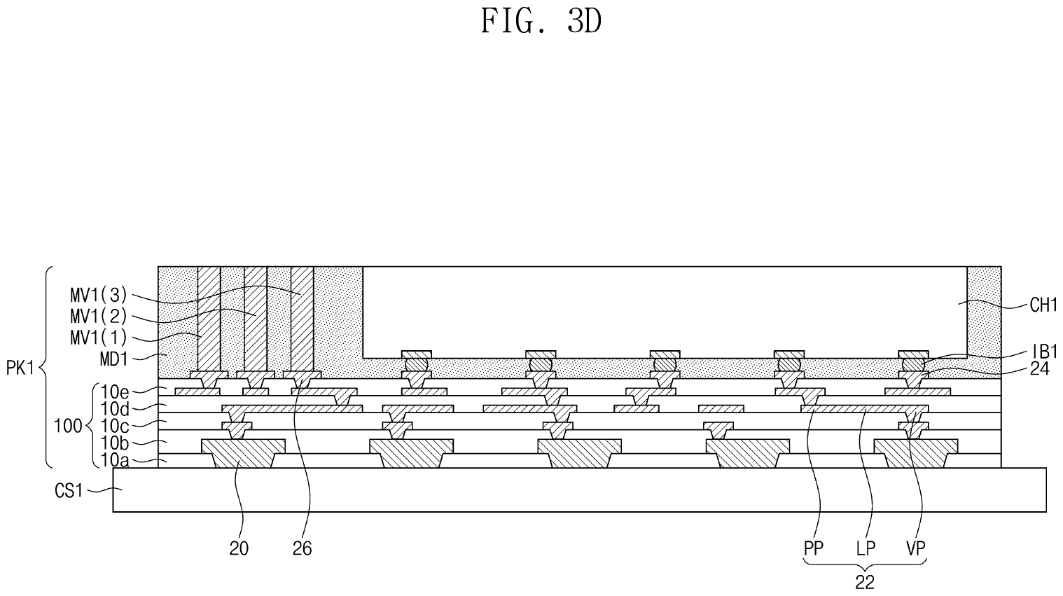

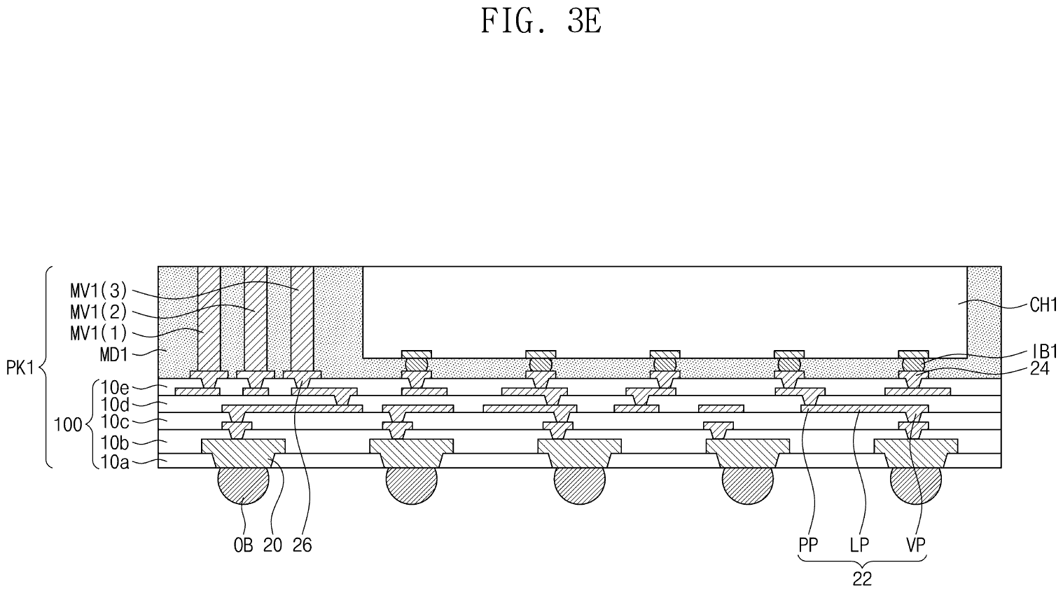

FIGS. 3A to 3E are sectional views illustrating a process of fabricating the first sub-package of FIG. 1.

Referring to FIG. 3A, the package substrate 100 may be formed on a first carrier substrate CS1. For this, a first substrate insulating layer 10a may be formed on the first carrier substrate CS1 and may be patterned to form trenches. A plating process may be performed on the first substrate insulating layer 10a to form the substrate lower pads 20. Second to fifth substrate insulating layers 10b to 10e, the substrate inner interconnection lines 22, and the first and second substrate upper pads 24 and 26 may be formed by repeating these processes.

Referring to FIG. 3B, the first mold vias MV1 may be formed on the package substrate 100. For this, a photoresist pattern may be formed on the package substrate 100. The photoresist pattern may include holes, which define the shapes of the first mold vias MV1 and are formed to expose the second substrate upper pads 26. A plating process may be performed to form the first mold vias MV1 in the holes, and then, the photoresist pattern may be removed to expose the top surface of the package substrate 100.

Referring to FIG. 3C, the first chip structure CH1 may be mounted on the package substrate 100. The first chip structure CH1 may be bonded to the first substrate upper pads 24 with the first inner connection members IB1 interposed therebetween. Next, the first mold layer MD1 may be formed on the package substrate 100. Here, the first mold layer MD1 may cover top surfaces of the first mold vias MV1 and a top surface of the first chip structure CH1.

Referring to FIG. 3D, a grinding process may be performed on the first mold layer MD1 to remove a portion of the first mold layer MD1 on the first mold vias MV1 to expose top surfaces of the first mold vias MV1. In an embodiment, the first chip structure CH1 may also be partially removed during the grinding process to have a reduced thickness.

Referring to FIG. 3E, the first carrier substrate CS1 below the package substrate 100 may be removed. Next, the outer connection terminals OB may be placed below and bonded to the package substrate 100. Thus, the first sub-package PK1 may be fabricated.

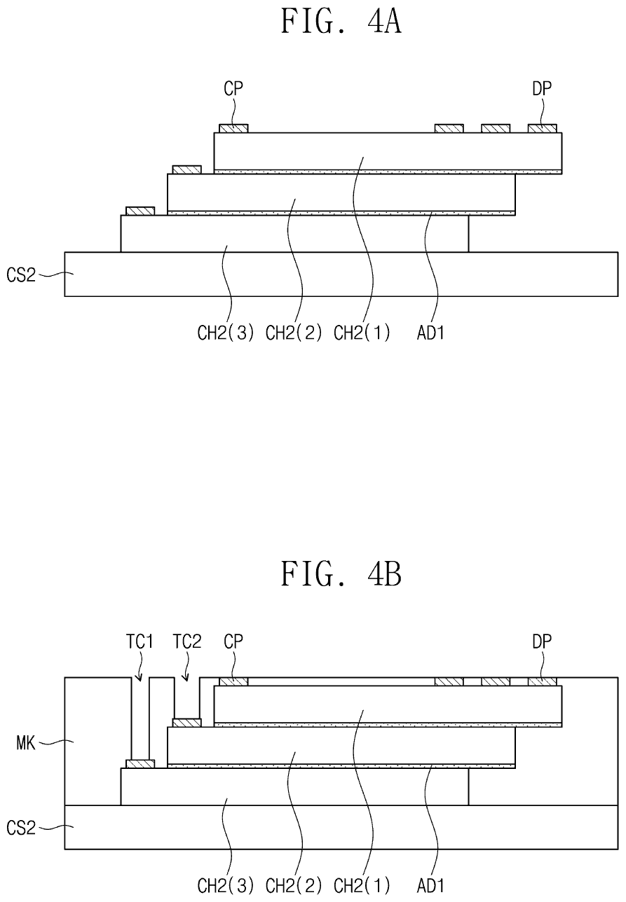

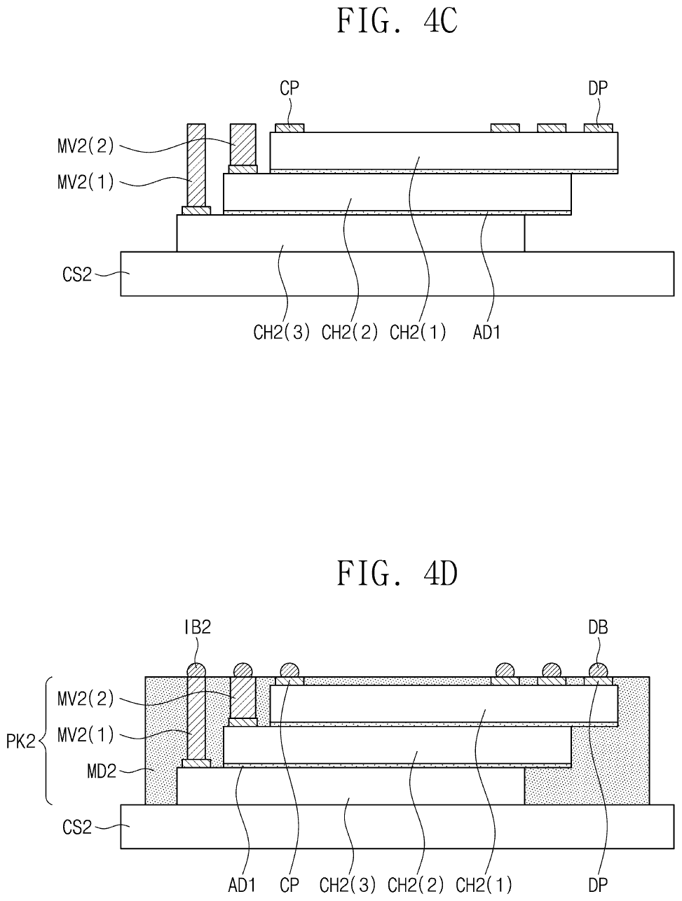

FIGS. 4A to 4D are sectional views illustrating a process of fabricating the second sub-package of FIG. 1.

Referring to FIG. 4A, the second chip structures CH2 may be stacked on a second carrier substrate CS2 to be offset from each other. For example, the second chip structures CH2 may collectively have a staircase structure or a staircase arrangement. The chip pads CP may be formed on end portions of the second chip structures CH2, and in an embodiment, the chip pads CP may be offset from each other. The first adhesive layer AD1 may be interposed between the second chip structures CH2 and may be used to increase an adhesion strength therebetween. The dummy pads DP may be formed on a top surface of the first of the second chip structures CH2(1), which is the uppermost one of the second chip structures CH2. The dummy pads DP may be formed to have the same height as the chip pads CP.

Referring to FIG. 4B, a mask pattern MK may be formed on the second carrier substrate CS2 to cover the second chip structures CH2. In an embodiment, the mask pattern MK may be a photoresist pattern. The mask pattern MK may include a first hole TC1 exposing the chip pad CP of the third of the second chip structures CH2(3) and a second hole TC2 exposing the chip pad CP of the second of the second chip structures CH2(2). The first hole TC1 may have a depth and width different from those of the second hole TC2. The depth of the first hole TC1 may be larger than the depth of the second hole TC2, and the width of the first hole TC1 may be smaller than the width of the second hole TC2. A top surface of the mask pattern MK may be coplanar with top surfaces of the chip pad CP of the first of the second chip structures CH2(1) and the dummy pads DP.

Referring to FIG. 4C, a plating process may be performed to form the second mold vias MV2. The first of the second mold vias MV2(1) may be formed in the first hole TC1, and the second of the second mold vias MV2(2) may be formed in the second hole TC2. For example, the first of the second mold vias MV2(1) may be formed on the chip pad CP of the third of the second chip structures CH2(3) (e.g., the lowermost one of the second chip structures), and the second of the second mold vias MV2(2) may be formed on the chip pad CP of the second of the second chip structures CH2(2) (e.g., an intermediate one of the second chip structures). Since the first and second holes TC1 and TC2 are formed to have different widths and depths from each other, the second mold vias MV2 having different sizes may be formed at the same time, and top surfaces of the second mold vias MV2 may be located at the same level. The mask pattern MK may be removed, after the formation of the second mold vias MV2.

Referring to FIG. 4D, the second mold layer MD2 may be formed on the second carrier substrate CS2. The second mold layer MD2 may cover the second chip structures CH2 and may fill a space between the second mold vias MV2 and a space between the chip pad CP and the dummy pads DP. The second mold layer MD2 may be formed to have a top surface that is coplanar with top surfaces of the second mold vias MV2 and top surfaces of the chip and dummy pads CP and DP. After the formation of the second mold layer MD2, the second inner connection members IB2 may be formed on top surfaces of the second mold vias MV2 and a top surface of the chip pad CP. At the same time, the dummy connection members DB may be formed on the dummy pads DP. The second inner connection members IB2 may have the same structure, material, and shape as the dummy connection members DB. As a result, the second sub-package PK2 may be fabricated. The second sub-package PK2 may be separated from the second carrier substrate CS2.

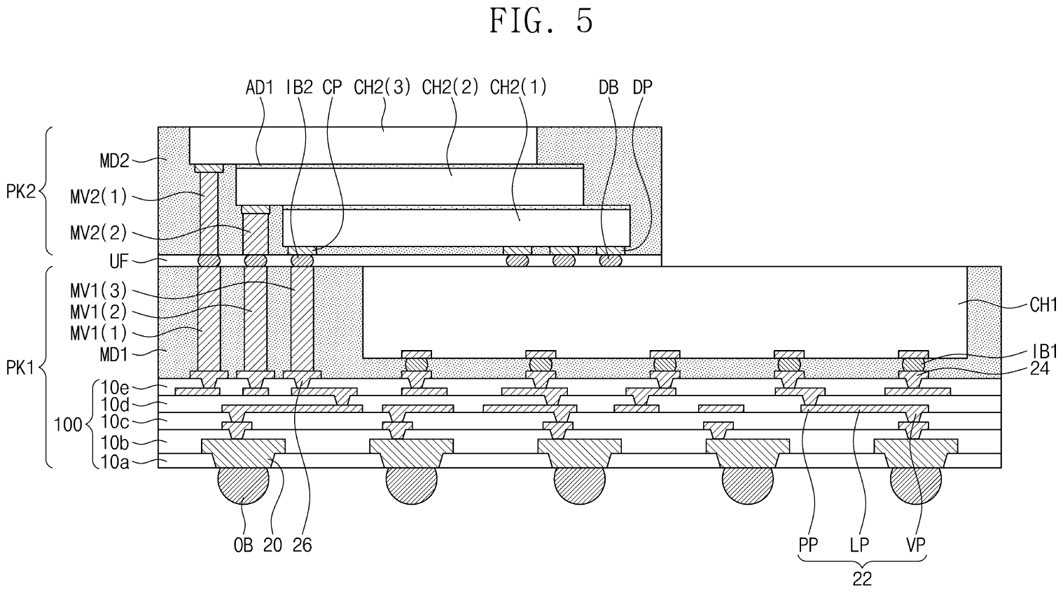

FIG. 5 is a sectional view illustrating a process of fabricating the semiconductor package of FIG. 1.

Referring to FIG. 5, the second sub-package PK2 of FIG. 4D may be inverted and may be placed on the first sub-package PK1. The second inner connection members IB2 may be placed to be in contact with top surfaces of the first mold vias MV1, the dummy connection members DB may be placed to be in contact with a top surface of the first chip structure CH1, and then, a reflow process may be performed. Thus, the second inner connection members IB2 may be bonded to the first mold vias MV1, and the dummy connection members DB may be bonded to the first chip structure CH1. Next, the under-fill layer UF may be formed between the first and second sub-packages PK1 and PK2. Referring back to FIG. 1, the heat-dissipation member HS may be placed on the first sub-package PK1 and next to the second sub-package PK2, and here, the heat-dissipation member HS and the first sub-package PK1 may be bonded to each other by the second adhesive layer AD2 interposed therebetween. As a result, the semiconductor package 1000 may be fabricated/completed to have the same structure as that in FIG. 1. Each of the heat-dissipation members HS disclosed in the present application may be a heat sink configured to dissipate heat generated from the corresponding semiconductor package.

In a method of fabricating a semiconductor package according to the inventive concept, an additional substrate may not be formed on the first sub-package PK1, the second sub-package PK2 may not include an additional substrate, and the second sub-package PK2 may be mounted on the first sub-package PK1 using the second inner connection members IB2. Accordingly, the fabrication process of the semiconductor package may be simplified and yield of semiconductor packages may increase. In addition, the dummy pads DP and the dummy connection members DB may be used to maintain the horizontal level of the second sub-package PK2, and thus, process failures may be reduced.

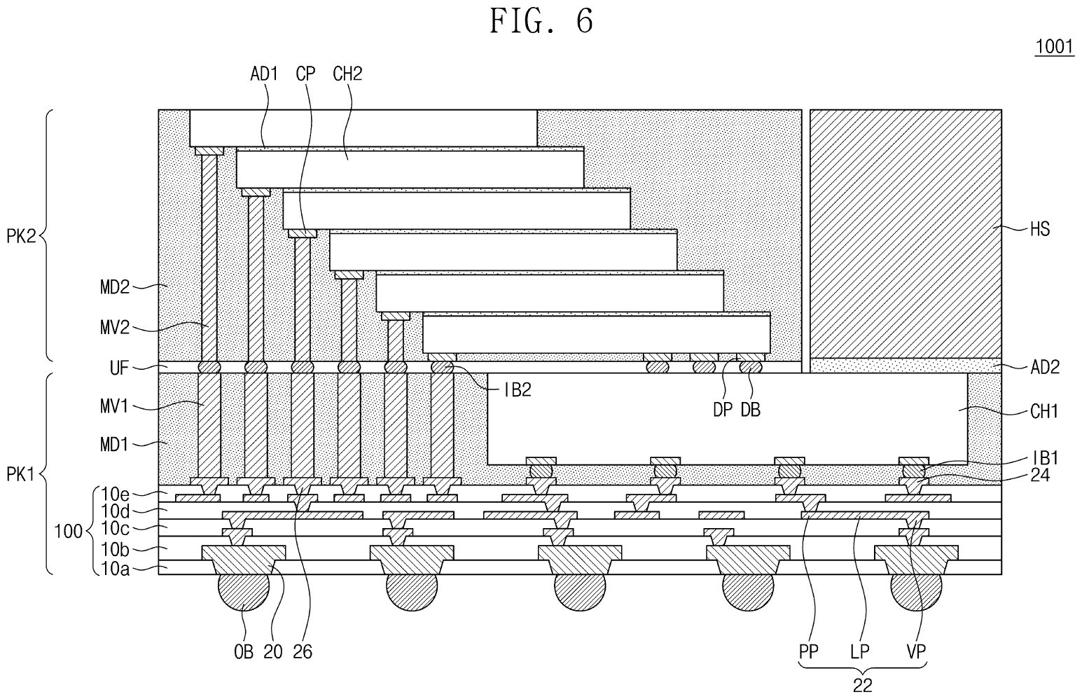

FIG. 6 is a sectional view illustrating a semiconductor package according to an embodiment of the inventive concept.

Referring to FIG. 6, in a semiconductor package 1001 according to the present embodiment, the second sub-package PK2 may include six second chip structures CH2. The second chip structures CH2 may be stacked to be offset from each other. In this case, five second mold vias MV2 may be provided. The second mold vias MV2 may be provided to have the same width. Except for the above features, the semiconductor package may be configured to have substantially the same features as one of the semiconductor packages described with reference to FIGS. 1 to 2C. For example, the remaining components of the semiconductor package 1001 may be the same as the ones of any one of the semiconductor packages described with reference to FIGS. 1 to 2C.

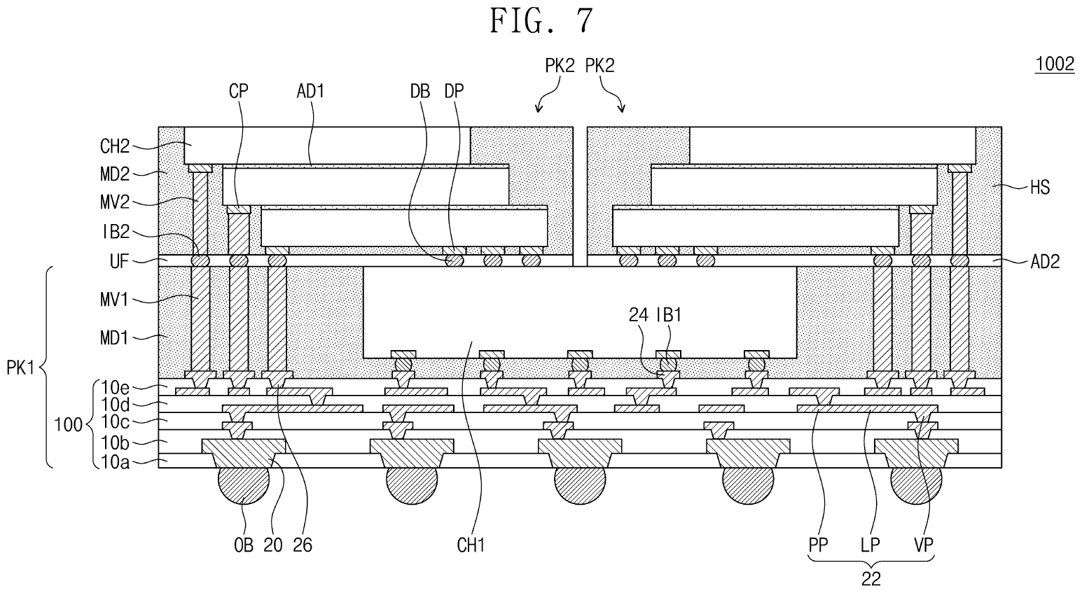

FIG. 7 is a sectional view illustrating a semiconductor package according to an embodiment of the inventive concept.

Referring to FIG. 7, in a semiconductor package 1002 of the present embodiment, two second sub-packages PK2 may be stacked on one first sub-package PK1. The second sub-packages PK2 may be placed symmetrically to each other. For example, the two second sub-packages PK2 may have mirror-image shapes with respect to each other. For example, the two second sub-packages PK2 may be arranged to have mirror-image symmetry or reflection symmetry with respect to a vertical plane passing between the two second sub-packages PK2 and through a center of the semiconductor package 1002. First mold vias MV1 in the first sub-package PK1 may be arranged at both sides of the first chip structure CH1 to be symmetric with respect to each other. For example, the first mold vias MV1 in the first sub-package PK1 may be arranged opposite sides of the first chip structure CH1 to have mirror image shapes with respect to each other. The semiconductor package 1002 may not include the heat-dissipation member HS and the second adhesive layer AD2 of FIG. 1. Except for the above features, the semiconductor package may be configured to have substantially the same features as one of the semiconductor packages described with reference to FIGS. 1 to 2C. For example, the remaining components of the semiconductor package 1002 may be the same as the ones of any one of the semiconductor packages described with reference to FIGS. 1 to 2C.

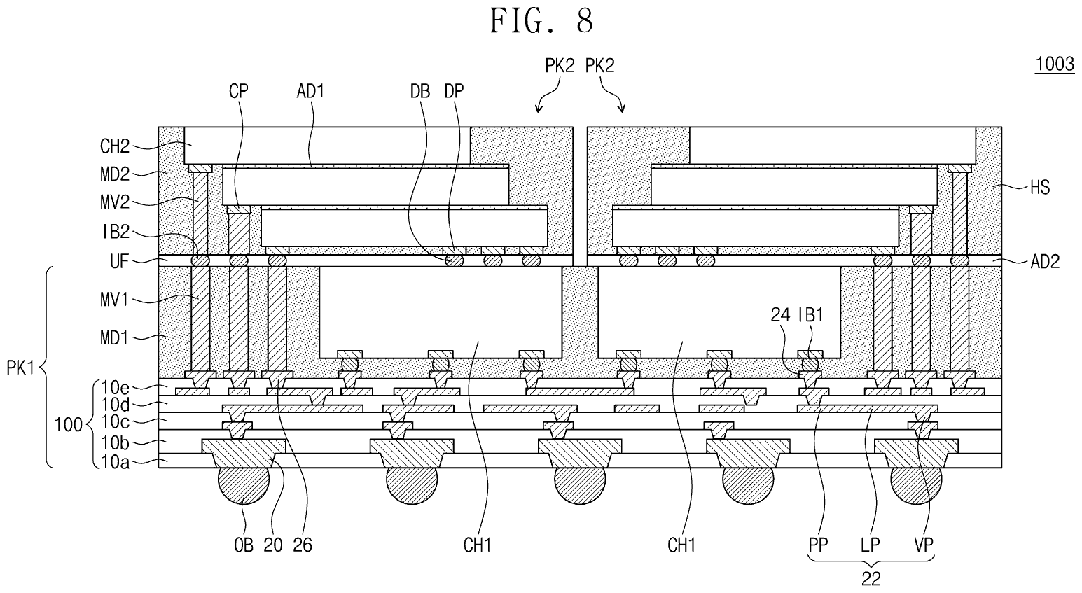

FIG. 8 is a sectional view illustrating a semiconductor package according to an embodiment of the inventive concept.

Referring to FIG. 8, in a semiconductor package 1003 according to the present embodiment, two second sub-packages PK2 may be stacked on one first sub-package PK1. The second sub-packages PK2 may be placed symmetrically to each other. For example, the two second sub-packages PK2 may have mirror-image shapes with respect to each other. For example, the two second sub-packages PK2 may be arranged to have mirror-image symmetry or reflection symmetry with respect to a vertical plane passing between the two second sub-packages PK2 and through a center of the semiconductor package 1003. The first sub-package PK1 may include two first chip structures CH1. The first chip structures CH1 may be disposed adjacent to a center portion of the package substrate 100, and first mold vias MV1 may be disposed on edge portions of the package substrate 100. The first chip structures CH1 may be electrically connected to each other by substrate inner interconnection lines 22, which are formed in the package substrate 100. Except for the above features, the semiconductor package may be configured to have substantially the same features as the semiconductor package described with reference to FIG. 7. For example, the remaining components of the semiconductor package 1003 may be the same as the ones of the semiconductor package 1002 described with reference to FIG. 7.

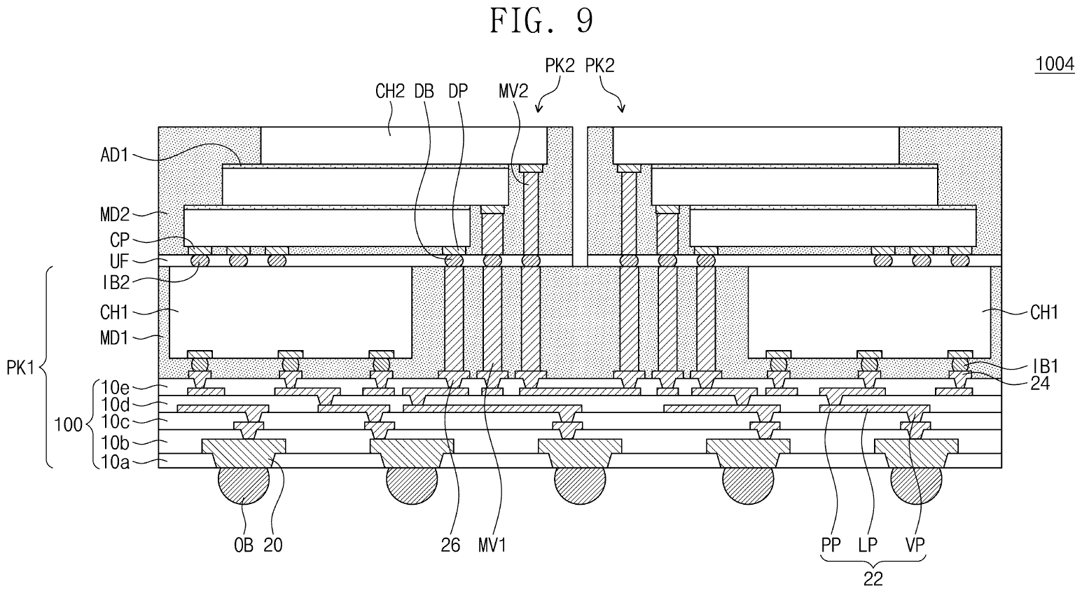

FIG. 9 is a sectional view illustrating a semiconductor package according to an embodiment of the inventive concept.

Referring to FIG. 9, in a semiconductor package 1004 according to the present embodiment, two second sub-packages PK2 may be stacked on one first sub-package PK1. The second sub-packages PK2 may be placed symmetrically to each other. For example, the two second sub-packages PK2 may have mirror-image shapes with respect to each other. For example, the two second sub-packages PK2 may be arranged to have mirror-image symmetry or reflection symmetry with respect to a vertical plane passing between the two second sub-packages PK2 and through a center of the semiconductor package 1004. The first sub-package PK1 may include two first chip structures CH1. The first chip structures CH1 may be disposed adjacent to the edge portion of the package substrate 100, and first mold vias MV1 may be disposed adjacent to the center portion of the package substrate 100. For example, the first mold vias MV1 may be positioned closer to a center of the package substrate 100 than the first chip structures CH1, e.g., in a plan view. Some of the first mold vias MV1 may be electrically connected to each other by the substrate inner interconnection lines 22 in the package substrate 100. Except for the above features, the semiconductor package may be configured to have substantially the same features as the semiconductor package described with reference to FIG. 8. For example, the remaining components of the semiconductor package 1004 may be the same as the ones of the semiconductor package 1003 described with reference to FIG. 8.

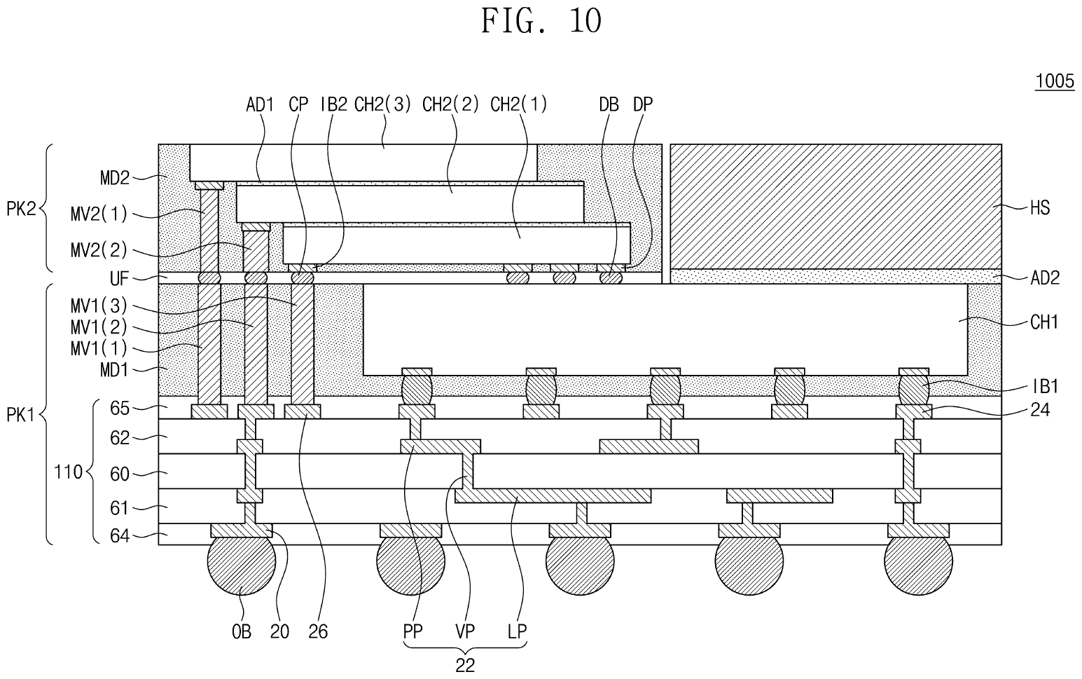

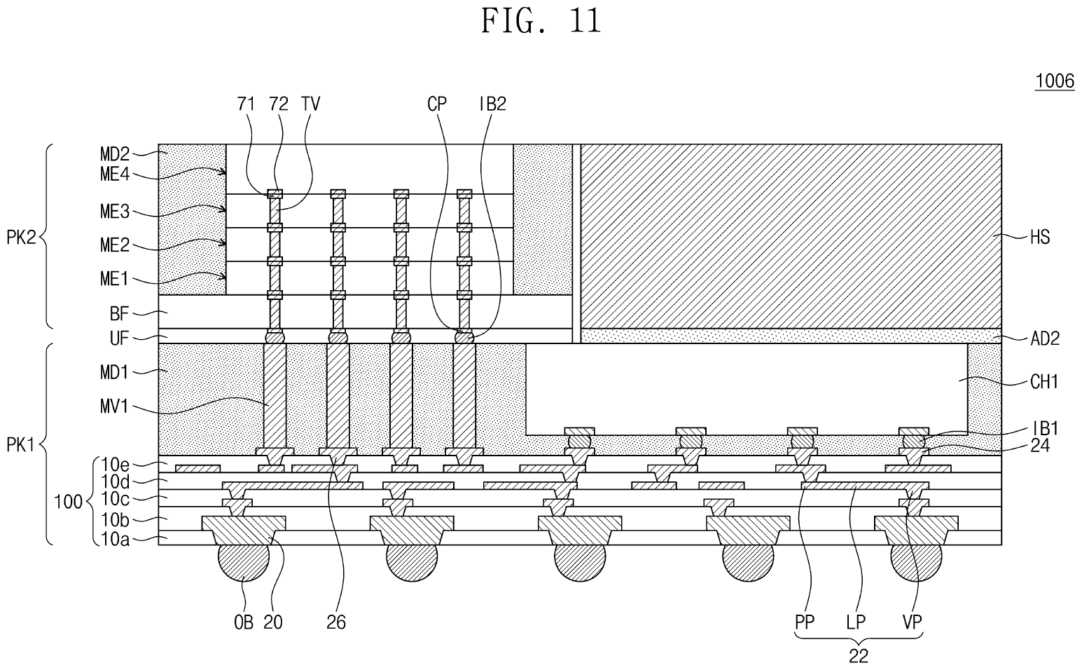

FIG. 10 is a sectional view illustrating a semiconductor package according to an embodiment of the inventive concept.

Referring to FIG. 10, in a semiconductor package 1005 according to the present embodiment, a first sub-package PK1 may include a package substrate 110. In the present embodiment, the package substrate 110 may be a multi-layered printed circuit board. The package substrate 110 may include a core layer 60, a first substrate insulating layer 62 and a first photo solder resist layer 65, which are sequentially stacked on the core layer 60, and a second substrate insulating layer 61 and a second photo solder resist layer 64, which are sequentially provided under the core layer 60. Each of the core layer 60, the first substrate insulating layer 62, and the second substrate insulating layer 61 may be formed of or include at least one of thermosetting resins (e.g., epoxy resin), thermoplastic resins (e.g., polyimide), composite materials (e.g., prepreg), in which a reinforcement element (e.g., glass fiber and/or inorganic filler) is pre-impregnated with a thermoplastic or thermosetting resin matrix, or photo-curable resins, but the inventive concept is not limited to these examples. A portion (e.g., the via portion VP) of the substrate inner interconnection line 22 may be provided to penetrate the core layer 60, and the line portions LP and pad portions PP may be connected to (e.g., contact) top and bottom ends of the via portion VP. A portion of the substrate lower pads 20 may be covered with the second photo solder resist layer 64. At least a portion of the substrate upper pads 24 and 26 may be covered with the first photo solder resist layer 65. Except for the above features, the semiconductor package may be configured to have substantially the same features as one of the semiconductor packages described with reference to FIGS. 1 to 2C. For example, the remaining components of the semiconductor package 1005 may be the same as the ones of any one of the semiconductor packages described with reference to FIGS. 1 to 2C.

FIG. 11 is a sectional view illustrating a semiconductor package according to an embodiment of the inventive concept.

Referring to FIG. 11, in a semiconductor package 1006 according to the present embodiment, a second sub-package PK2 may have a high bandwidth memory (HBM) chip structure. The second sub-package PK2 may include a buffer die BF, memory dies ME1 to ME4, and the second mold layer MD2. The buffer die BF may be used to process data or to exchange data with the memory dies ME1 to ME4 (e.g., for transmission to or reception from the memory dies ME1 to ME4). The memory dies ME1 to ME4 may be the same memory chips (e.g., DRAM chips). The first to fourth memory dies ME1 to ME4 may be stacked on the buffer die BF. Side surfaces of the first to fourth memory dies ME1 to ME4 may be aligned to (e.g., vertically overlap) each other. The number of the memory dies ME1 to ME4 is not limited to four and may be greater than one. Each of the first to third memory dies ME1 to ME3 and the buffer die BF, except for the uppermost one ME4, may include penetration vias TV and upper connection pads 71. The first to fourth memory dies ME1 to ME4 may include lower connection pads 72. The buffer die BF and the memory dies ME1 to ME4 may be provided in such a way that the lower connection pads 72 of one die are in contact with the upper connection pads 71 of an adjacent die. Penetration vias TV, which are placed on one first mold via MV1, may vertically overlap each other and may vertically overlap respective first mold vias MV1. Except for the above features, the semiconductor package may be configured to have substantially the same features as one of the semiconductor packages described with reference to FIGS. 1 to 2C. For example, the remaining components of the semiconductor package 1006 may be the same as the ones of any one of the semiconductor packages described with reference to FIGS. 1 to 2C.

In a semiconductor package according to an embodiment of the inventive concept, an additional substrate may not be interposed between a first sub-package and a second sub-package which are stacked, and the second sub-package may not include an additional substrate. For example, the second sub-package may not include any substrate, and no substrate is interposed between the first sub-package and the second sub-package. First mold vias of the first sub-package may be electrically connected to second mold vias of the second sub-package by inner connection members. Accordingly, a connection distance between a first chip structure of the first sub-package and a second chip structure of the second sub-package may be reduced, and thus, a signal transmission speed may be increased between the first chip structure and the second chip structure. In addition, a total vertical thickness of the semiconductor package may be reduced, and this may improve heat-dissipation performance and reliability of the semiconductor package and reduce malfunction issues in the semiconductor package.

In a method of fabricating a semiconductor package according to an embodiment of the inventive concept, a fabrication process of a semiconductor package may be simplified, process failures in fabricating semiconductor packages may be reduced, and yield of semiconductor packages may be increased.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While example embodiments of the inventive concept have been particularly shown and described, it will be understood by one of ordinary skill in the art that variations in form and detail may be made therein without departing from the spirit and scope of the attached claims. The embodiments of FIGS. 1 to 11 may be variously combined to realize the inventive concept of the present invention.

1. A semiconductor package, comprising:
a first sub-package;
a second sub-package stacked on the first sub-package; and
a first inner connection terminal interposed between the first and second sub-packages to electrically connect them to each other,
wherein the first sub-package comprises:
a package substrate;
a first chip mounted on the package substrate;
a first mold layer covering the package substrate and the first chip; and
a first mold via provided next to the first chip to penetrate the first mold layer,
wherein the second sub-package comprises:
second chips, which are sequentially stacked to be offset from each other,
the second chips comprising chip pads exposed through bottom surfaces of the second chips;
a second mold layer covering the second chips; and
a second mold via penetrating a portion of the second mold layer and in contact with a chip pad of the uppermost one of the second chips,
wherein the first inner connection terminal is in contact with the first and second mold vias.

2. The semiconductor package of claim 1, wherein the first inner connection terminal vertically overlaps the first and second mold vias.

3. The semiconductor package of claim 1, wherein a width of the first mold via is different from a width of the second mold via.

4. The semiconductor package of claim 1, wherein the number of the second chips is three or more,
the second sub-package further comprises a third mold via, which is electrically connected to a chip pad of an intermediate one of the second chips and penetrates a portion of the second mold layer,
the second mold via has a first height and a first width,
the third mold via has a second height and a second width,
the second height is smaller than the first height, and
the second width is larger than the first width.

5. The semiconductor package of claim 4, wherein the first chip further comprises a fourth mold via, which penetrates the first mold layer and is electrically connected to the third mold via, and
the semiconductor package further comprises a second inner connection terminal electrically connecting the third mold via to the fourth mold via.

6. The semiconductor package of claim 1, wherein the lowermost one of the second chips further comprises at least one dummy pad provided on a bottom surface of the lowermost one.

7. The semiconductor package of claim 1, further comprising a heat sink on the first chip and next to the second chips.

8. The semiconductor package of claim 1, wherein the second mold layer covers a bottom surface of the lowermost one of the second chips.

9. The semiconductor package of claim 1, wherein the first inner connection terminal comprises:
a conductive bump in contact with a bottom surface of the second mold via; and
a solder layer interposed between the conductive bump and the first mold via,
wherein a width of the conductive bump is different from a width of at least one of the first and second mold vias.

10. The semiconductor package of claim 1, wherein an aspect ratio of the first mold via is in a range from 6 to 1000.

11. A semiconductor package, comprising:
a first sub-package;
a second sub-package stacked on the first sub-package; and
a first inner connection terminal and a second inner connection terminal interposed between the first sub-package and the second sub-package to electrically connect them to each other,
wherein the first sub-package comprises:
a package substrate;
a first chip mounted on the package substrate;
a first mold layer covering the package substrate and the first chip; and
a first mold via and a second mold via provided next to the first chip to penetrate the first mold layer,
wherein the second sub-package comprises:
at least three second chips, which are sequentially stacked to be offset from each other, the second chips comprising chip pads exposed through bottom surfaces of the second chips;
a second mold layer covering the second chips;
a third mold via penetrating a portion of the second mold layer and contacting a chip pad of the uppermost one of the second chips; and
a fourth mold via penetrating a portion of the second mold layer and electrically connected to a chip pad of an intermediate one of the second chips,
wherein the first inner connection terminal vertically overlaps the first and third mold vias,
the second inner connection terminal vertically overlaps the second and fourth mold vias,
the third mold via has a first height and a first width,
the fourth mold via has a second height and a second width,
the second height is smaller than the first height,
the second width is larger than the first width, and
an aspect ratio of each of the first and second mold vias is in a range from 6 to 1000.

12. The semiconductor package of claim 11, wherein the lowermost one of the second chips further comprises at least one dummy pad placed on a bottom surface thereof.

13. The semiconductor package of claim 11, further comprising a heat sink on the first chip and next to the second chips.

14. The semiconductor package of claim 11, wherein the second mold layer covers a bottom surface of the lowermost one of the second chips.

15. The semiconductor package of claim 11, wherein the first inner connection terminal comprises:
a conductive bump in contact with a bottom surface of the third mold via; and
a solder layer interposed between the conductive bump and the first mold via,
wherein a width of the conductive bump is different from a width of at least one of the first and third mold vias.

16. A semiconductor package, comprising:
a first sub-package;
a second sub-package stacked on the first sub-package; and
a first inner connection terminal interposed between the first sub-package and the second sub-package to electrically connect them to each other,
wherein the first sub-package comprises:
a package substrate;
a first chip mounted on the package substrate;
a first mold layer covering the package substrate and the first chip; and
a first mold via provided next to the first chip to penetrate the first mold layer,
wherein the second sub-package comprises:
second chips, which are sequentially stacked to be offset from each other,
the second chips comprising chip pads exposed through bottom surfaces of the second chips;
a second mold layer covering the second chips; and
a second mold via penetrating a portion of the second mold layer and contacting a chip pad of the uppermost one of the second chips,
wherein the lowermost one of the second chips further comprises at least one dummy pad, which is provided on a bottom surface of the lowermost one and is in contact with the first chip.

17. The semiconductor package of claim 16, wherein the first inner connection terminal is in contact with the first and second mold vias.

18. The semiconductor package of claim 16, wherein the first inner connection terminal vertically overlaps the first and second mold vias.

19. The semiconductor package of claim 16, wherein a width of the first mold via is different from a width of the second mold via.

20. The semiconductor package of claim 16, wherein the number of the second chips is three or more,
the second sub-package further comprises a third mold via, which is electrically connected to a chip pad of an intermediate one of the second chips and penetrates a portion of the second mold layer,
the second mold via has a first height and a first width,
the third mold via has a second height and a second width,
the second height is smaller than the first height, and
the second width is larger than the first width.

21. (canceled)
